(19) United States
(12) Patent Application Publication
(10) Pub. No.: US 2026/0337379 A1
(43) Pub. Date: Oct. 29, 2026

(54) COMPOSITE MATERIAL

(71) Applicant: Murata Manufacturing Co., Ltd., Nagaokakyo-shi (JP)

(72) Inventors: Takayuki KONO, Nagaokakyo-shi (JP); Hiroyuki MORITA, Nagaokakyo-shi (JP); Yasunori HIOKI, Nagaokakyo-shi (JP); Takeshi TORITA, Nagaokakyo-shi (JP)

(21) Appl. No.: 19/702,084

(22) Filed: Jun. 9, 2026

Related U.S. Application Data
(63) Continuation of application No. PCT/JP2024/043627, filed on Dec. 10, 2024.
(60) Provisional application No. 63/609,383, filed on Dec. 13, 2023.

(51) Int. Cl. C08K 7/08; C09K 5/14

(52) U.S. Cl. CPC C08K 7/08; C09K 5/14; C08K 2201/001; C08K 2201/011

(57) ABSTRACT

A composite material comprising: a resin having a negative zeta potential; and a material containing a nanofiber and/or a two-dimensional substance represented by; MQₐO_{b}, wherein M is one or more elements selected from the group consisting of Groups 3, 4, 5, 6, and 7, Q is one or more elements selected from the group consisting of Groups 12, 13, 14, 15, and 16, excluding O, a is not less than 0 and not more than 2, and b is greater than 0 and not more than 2.

### CROSS REFERENCE TO RELATED APPLICATIONS

The present application is a continuation of International application No.

PCT/JP 2024/043627, filed Dec. 10, 2024, which claims priority to U.S. Provisional Patent Application No. 63/609,383, filed Dec. 13, 2023, the entire contents of each of which are incorporated herein by reference.

### TECHNICAL FIELD

The present disclosure relates to a composite material.

### BACKGROUND ART

Conventionally, for example, TiO₂ is known as a metal-containing oxide. For example, AEROXIDE (registered trademark) TiO₂ P-25 is a hydrophilic titanium dioxide having a particle size of 20 to 30 nm, and is a titanium oxide having a very high specific surface area. For example, as shown in Non-Patent Document 1, it is known that titanium dioxide is suitable for many catalytic actions, particularly suitable for applications of photocatalysts due to the ratio between the anatase crystal structure and the rutile crystal structure, and gives self-purification in, for example, an inorganic composition due to the effect of the photocatalyst.

Non-patent Document 1: Teruhisa Ohno, Koji Sarukawa, Kojiro Tokieda, Michio Matsumura, Morphology of a TiO2 Photocatalyst (Degussa, P-25) Consisting of Anatase and Rutile Crystalline Phases, Journal of Catalysis, Volume 203, Issue 1, 2001, Pages 82-86

### SUMMARY OF THE DISCLOSURE

It is known that TiO₂ has a problem in that it is difficult to disperse in an aqueous polymer solution and aggregates. Therefore, even when a coating film or the like is formed using an aqueous polymer solution containing TiO₂, a coating film or the like in which TiO₂ is dispersed is not obtained. Therefore, it is also difficult to use the coating film as, for example, a thermally conductive material. In order to enhance the dispersibility of TiO₂ in an aqueous polymer solution, it is conceivable to add a dispersant to the aqueous polymer solution. However, the presence of the dispersant may deteriorate required characteristics such as thermal conductivity. Furthermore, there is also a problem that the dispersant may bleed out.

The present disclosure has been made in view of the above circumstances, and an object of the present disclosure is to provide a novel composite material having high dispersibility and suitable for production of a film or the like having desired characteristics.

According to one aspect of the present disclosure, there is provided a composite material comprising: a resin having a negative zeta potential; and a nanofiber and/or a two-dimensional substance represented by:

MQₐO_{b}

wherein M is one or more elements selected from the group consisting of Groups 3, 4, 5, 6, and 7,

Q is one or more elements selected from the group consisting of Groups 12, 13, 14, 15, and 16, excluding O,

a is not less than 0 and not more than 2, and

b is greater than 0 and not more than 2.

According to the present disclosure, a novel composite material containing a predetermined material and a resin and having high dispersibility of the predetermined material is provided.

### BRIEF DESCRIPTION OF THE DRAWINGS

FIG. 1 is an explanatory view concerning the fracture when a conventional polymer composite containing TiO₂ as a filler is pulled.

FIG. 2 is an explanatory view concerning the fracture of a polymer composite containing MQO particles of the present embodiment as a filler.

FIG. 3 is a graph showing a result of Raman spectroscopy of a material (TiCO) produced in Examples.

FIG. 4 is an XRD pattern of a material (TiCO) produced in Examples.

FIG. 5 is an XRD pattern of a material (TiCO/polyurethane composite material) produced in Examples.

FIG. 6 is a view in which the XRD patterns of FIG. 4 and FIG. 5 are overlaid.

FIG. 7 shows a result of evaluating dispersibility of an aqueous dispersion of titanium dioxide (TiO₂) in Comparative Examples.

FIG. 8 shows a result of evaluating dispersibility of an aqueous polyurethane dispersion of titanium dioxide (TiO₂) in Comparative Examples.

FIG. 9 shows a result of evaluating dispersibility of a poly(ethyleneimine) dispersion of a material (TiCO) produced in Comparative Examples.

FIG. 10 shows a result of evaluating dispersibility of an aqueous polyurethane dispersion of a material (TiCO) produced in Examples.

FIG. 11 shows a result of evaluating dispersibility of an aqueous acrylic resin dispersion of a material (TiCO) produced in Examples.

### DETAILED DESCRIPTION

### Composite Material

The present embodiment relates to a composite material containing a material containing a predetermined nanofiber and/or two-dimensional substance. In the present disclosure, simply referring to “material” means “material containing a nanofiber and/or a two-dimensional substance” (in other words, a material containing at least one of a nanofiber and a two-dimensional substance). In the present embodiment, the material containing a nanofiber and/or a two-dimensional substance typically means a material that is solid and does not contain a binder or the like (for example, a polymer). The material containing a nanofiber and/or a two-dimensional substance can mean, in a narrow sense, a material substantially composed of at least one of a nanofiber and a two-dimensional substance (which may contain other objects, impurities, or the like that may be inevitably mixed). However, the material containing a nanofiber and/or a two-dimensional substance is not limited thereto. (MQO-containing material)

The material contained in the composite material of the present embodiment is a nanofiber and/or a two-dimensional substance of a predetermined material (substance). The predetermined material that can be used in the present embodiment is represented by the following Formula (1).

MQₐO_{b} . . . (1)

wherein M is one or more elements selected from the group consisting of Groups 3, 4, 5, 6 and 7, and may contain a so-called early transition metal, for example, one or more elements selected from the group consisting of Sc, Ti, Zr, Hf, V, Nb, Ta, Cr, Mo and Mn, and preferably one or more elements selected from the group consisting of Ti, V, Cr, Mo and Mn,

Q is one or more elements selected from the group consisting of Groups 12, 13, 14, 15, and 16, excluding O, and may contain, for example, one or more elements selected from the group consisting of B, C, N, Si, P, and S, a is not less than 0 and not more than 2, and b is greater than 0 and not more than 2.

Hereinafter, the predetermined material is also simply referred to as “MQO”. Examples of MQO include those represented by formulas such as TiO₂, TiCO, TiCON, VO₂, VCO, VCON, CrO₂, CrCO, CrCON, MoO₂, MoCO, MoCON, MnO₂, MnCO, and MnCON. For example, in Formula (1), M may be Ti, and Q may be C. Furthermore, for example, in Formula (1), a may not be 0. That is, a may be more than 0, and may be, for example, 1 or more.

MQO has a crystal structure different from that of a hexagonal system. Although the present embodiment is not bound by any theory, it can be considered that the crystal structure of MQO is an anatase type crystal structure, a lepidocrocite type crystal structure, or a mixed crystal structure thereof at present. For example, the crystal structure of MQO may be a lepidocrocite type.

MQO can be produced using a first raw material and a second raw material, for example, as follows. The first raw material contains at least M, the second raw material contains at least Q, and the first raw material and the second raw material can react in a protic solvent to generate MQO.

As the first raw material, a material represented by the following Formula (2) can be used.

M_{c}A¹_{d} . . . (2)

wherein M is as described above,

A¹ is one or more elements selected from the group consisting of Groups 12, 13, 14, 15, and 16, and may contain, for example, one or more elements selected from the group consisting of B, C, N, O, Si, P, and S, c and d are each independently not less than 1 and not more than 5.

Provided that the material represented by Formula (2) needs to be different from the MQO of the product. Typically, the material represented by Formula (2) may not have a peak in a range in which the diffraction angle 2θ is not less than 2°and not more than 12°in an X-ray diffraction (XRD) pattern.

Examples of the first raw material represented by Formula (2) include TiB₂, TiB, TiC, TiN, TiO₂, Ti₅Si₃, Ti₂SbP, VO₂, V₂O₄, NbC, Nb₂O₅, MoO₂, MoO₃, MoS₂, MnO₂, Mn₃O₄, and MnCO₃. MnO₂ that can be used as the first raw material has a peak in the vicinity of 2θ=13° and does not have a peak in the range where 2θ is not less than 2° and not more than 12° in the XRD pattern.

Alternatively, or in addition to the above, a material represented by the following Formula (3) (hereinafter, also simply referred to as “MAX phase” or “MAX raw material”) can be used as the first raw material.

MₘA²Xₙ . . . (3)

wherein M is as described above,

X is one or more elements selected from the group consisting of C and N,

n is not less than 1 and not more than 4,

m is greater than n and not more than 5,

A² is one or more elements selected from the group consisting of Groups 12, 13, 14, 15, and 16, is usually a Group A element, typically Group IIIA and Group IVA, and more particularly may contain at least one selected from the group consisting of Al, Ga, In, Tl, Si, Ge, Sn, Pb, P, As, S, and Cd, and is preferably Al.

The MAX phase has a crystal structure in which a layer constituted of A² atoms is located between two layers represented by MₘXₙ (each X may have a crystal lattice located in an octahedral array of M). When typically m=n+1, the MAX phase includes repeating units in which each one layer of X atoms is disposed in between adjacent layers of n+1 layers of M atoms (these are also collectively referred to as an “MₘXₙ layer”), and a layer of A² atoms (“A² atom layer”) is disposed as a layer next to the (n+1)th layer of M atoms. However, the MAX phase is not limited thereto.

Examples of the first raw material represented by Formula (3) include Ti₃AlC₂, Ti₃GaC₂, and Ti₃SiC₂.

As the first raw material, the material represented by Formula (2) and the material represented by Formula (3) may be used together (for example, as a mixture).

As the second raw material, an ionically bondable substance having a carbon-containing group can be used. The ionically bondable substance having a carbon-containing group contains C. Examples of the ionically bondable substance include ammonium salts, phosphate salts, and sulfate salts.

More specifically, a quaternary ammonium salt can be used as the second raw material. Examples of the quaternary ammonium salt include tetramethylammonium hydroxide (TMAH), tetraethylammonium hydroxide (TEAH), tetrapropylammonium hydroxide (TPAH), tetrabutylammonium hydroxide (TBAH or TBAOH), benzyltrimethylammonium hydroxide, tetrabutylammonium fluoride (TBAF), tetrabutylammonium chloride (TBACl), tetrabutylammonium bromide (TBAB), tetrabutylammonium iodide (TBAI), benzyltriethylammonium chloride (BTEAC), hexadecyltrimethylammonium bromide, cetyltrimethylammonium bromide (CTAB), benzethonium chloride, benzalkonium chloride, and cetylpyridinium chloride (CPC). Among them, TMAH and TBAOH are preferable.

Alternatively, or in addition to the above, other ion-binding substances containing P and/or S and the like can be used as the second raw material.

The protic solvent may be any solvent that can at least partially dissolve the first raw material and the second raw material, and may be particularly an aqueous solvent. As the protic solvent, water, an alcohol (for example, ethanol, 1-propanol, isopropanol), a carboxylic acid (for example, acetic acid, formic acid), or the like is used. The aqueous solvent may be composed of water and optionally a liquid substance compatible with water (for example, a protic solvent other than water), and is preferably water.

The first raw material and the second raw material are reacted in a protic solvent. The second raw material can be added to the protic solvent in advance. The proportion of the second raw material in the total of the protic solvent and the second raw material may be, for example, 5 mass % or more, and particularly 20 mass % or more, and/or may be, for example, 80 mass % or less, and particularly 50 mass % or less. The first raw material can be further added to and mixed with the protic solvent to which the second raw material has been added. In such a mixture, a reaction for producing MQO proceeds. The temperature (reaction temperature) of the mixture (which may include the reaction product) may be, for example, 15 °C or higher, particularly 40 °C or higher, and/or, for example, 100 °C or lower, particularly 80 °C or lower. The mixing time (reaction time) may be, for example, 1 day or more, particularly, 2 days or more, and/or may be, for example, 10 days or less, particularly 7 days or less. The mixing can be performed, for example, by rotating and stirring with a stirring bar placed into the container using a magnetic stirrer while maintaining the reaction temperature by a hot plate stirrer and a hot water bath. However, the treatment operation and conditions (temperature, time, and the like) under which the reaction can proceed are not limited to the above, and may be appropriately selected according to the first raw material, the second raw material, the protic solvent, and the like to be used.

MQO is generated by the above reaction, and can eventually grow into MQO nanofibers, and further into MQO nanoflakes. Although the present disclosure is not limited, the resulting MQO nanofibers may be in the form of nanoribbons extending at nanoscale widths. In addition, a plurality of MQO nanofibers (for example, nanoribbons) may be bonded and/or integrated with each other to grow into nanoflakes extending two-dimensionally. In addition, a plurality of MQO nanoflakes may be stacked on each other (for example, by van der Waals force) to form a laminate. Although the present disclosure is not bound by any theory, the generation and growth of such MQO can be considered to be due to a bottom-up type synthesis reaction.

In the present disclosure, the cross-sectional outer dimension of the MQO nanofiber means the shortest distance passing through the center in the cross section crossing the longitudinal direction of the MQO nanofiber. The shape of the cross section of the MQO nanofiber is not particularly limited, but can be approximated by, for example, a rectangular shape (rectangle, square, and the like) or an ellipse, including a flattened ellipse or a circleelliptical shape (flat circle, true circle, and the like). When the MQO nanofibers are in the form of nanoribbons, the shape of the cross-section thereof can be approximated by a rectangle, and the cross-sectional outer dimension can correspond to the short side length of the rectangle. When the MQO nanofibers are in the form of nanofilaments, the shape of the cross section thereof can be approximated by a flat circle, and the cross-sectional outer dimension can correspond to the short diameter length of the flat circle.

In the present disclosure, MQO is a solid. MQO can typically be a particle (or powder).

The mixture after the reaction (also referred to as a reaction mixture) may be appropriately subjected to post-treatment. Examples of the post-treatment include washing, impact application (including shear force application), drying (for example, freeze drying, heat drying), and pulverization.

Washing may be performed using a protic solvent. The same description as above may apply to the protic solvent, and washing may be performed with, for example, water or alcohol as a protic solvent. After washing, a separation operation (centrifugation and/or decantation) may be carried out. Washing and separation operations may be repeated until the pH of the supernatant after centrifugation is, for example, 8 or less.

Optionally, washing may be performed using an aqueous solution of a metal salt instead of or in addition to the above washing. The metal salt may be, for example, a halide (fluoride, chloride, bromide, iodide) of an alkali metal (Li, Na, K, and the like), typically LiCl, NaCl, KCl, or the like. Specifically, for example, washing may be performed using a 1 to 10 M aqueous metal salt solution. After washing, a separation operation (centrifugation and/or decantation) may be carried out. Also in this case, washing and separation operations may be repeated as necessary until the pH of the supernatant after centrifugation becomes, for example, 8 or less.

During and/or after washing, an impact such as vibration and/or ultrasound may be applied. This makes it possible to promote dispersion or the like of MQO particles (for example, nanofibers/nanoflakes, the same applies to the following). When the MQO particles are aggregated, they can be disintegrated. Such an effect is remarkably obtained when an impact is applied during washing using an aqueous solution of a metal salt (it is considered that metal cations derived from the metal salt enter gaps of the aggregates, and thus enable disintegration). The impact can be imparted using, for example, any one or more of manual shaking, an automatic shaker, a mechanical shaker, a Vortex mixer, a homogenizer, an ultrasonic bath, and the like.

Since MQO particles are solid, a separation operation may be performed at any suitable timing to remove unwanted liquid components if present. As a final separation operation, for example, a drying operation, typically freeze drying or heat drying, may be performed. Freeze drying may be performed, for example, by freezing a mixture containing MQO particles and a liquid component at any suitable temperature (for example, −40 °C), followed by drying under a reduced pressure atmosphere. The heat drying can be performed, for example, by drying a mixture containing MQO particles and a liquid component at a temperature of 25 °C or higher (for example, 200 °C or lower) under a normal pressure or a reduced pressure atmosphere. The pulverization is not particularly limited, but can be performed using, for example, a combination of a mortar and a pestle, an IKA mill, or the like. Pulverization may be performed after drying.

Note that in order to obtain a material containing MQO (predetermined nanofiber and/or two-dimensional substance, typically, MQO particles. hereinafter, the material may be referred to as “MQO-containing material”) with a higher purity, it is preferable to repeat washing and centrifugation multiple times to recover the supernatant after final centrifugation. Such a supernatant may be used as it is as a slurry containing MQO particles, or may be appropriately diluted with a liquid medium or mixed with a liquid medium after drying to form a slurry containing MQO particles. A film prepared using such a slurry may be used as the composite material of the present embodiment.

As described above, MQO particles can be obtained as the MQO-containing material. Although MQO is represented by Formula (1), the MQO-containing material (typically, MQO particles) does not need to be composed of only the constituent elements of Formula (1). Although the present disclosure is not limited, the MQO-containing material may optionally have at least one selected from the group consisting of a hydroxyl group, a chlorine atom, an oxygen atom, a hydrogen atom, and a nitrogen atom, as the modification or terminal T present on the surface thereof. In addition, the MQO-containing material (typically, MQO particles) may have two or more layers, and at least one selected from the group consisting of ammonium ions (for example, quaternary ammonium cations) and metal cations (for example, alkali metal ions and alkaline earth metal ions) may exist between these layers.

The particle size of the MQO particles may be, for example, 0.01 nm or more, particularly 0.1 nm or more, 1 nm or more, and/or may be, for example, less than 1000 nm, particularly 100 nm or less, and further 50 nm or less. Such particles may also be referred to as nanoparticles.

The form of the MQO particle is a nanofiber and/or a two-dimensional substance. The two-dimensional substance includes one or more of nanoflakes and a laminate of nanoflakes. In the present embodiment, the two-dimensional substance is not limited to only the nanoflakes and the laminate of nanoflakes.

The nanofibers may also be referred to as nanowires. In the present disclosure, the “nanofiber” means a solid material extending in the longitudinal direction, and having an outer dimension (cross-sectional outer dimension) of a cross section perpendicular to the longitudinal direction on the order of nanometers (that is, not less than 1 nm and less than 1000 nm) or on the order of subnanometers (less than 1 nm, for example, not less than 0.1 nm and less than 1 nm) smaller than the order of nanometers. The longitudinal length of the nanofiber is not limited to the order of nanometers (that is, not less than 1 nm and less than 1000 nm), and may be in the order of microns (not less than 1 μm and less than 1000 μm). The cross-sectional outer dimension of the nanofiber may be, for example, 0.1 nm or more, particularly 1 nm or more, and may be, for example, 100 nm or less, particularly 50 nm or less, and preferably 15 nm or less.

In the present disclosure, the “two-dimensional substance” means a solid having a two-dimensionally extended surface (also referred to as a plane or a two-dimensional sheet surface) and having a thickness relatively small with respect to a maximum dimension of the surface (which may correspond to an “in-plane dimension” of a particle), the thickness being on the order of nanometers (that is, not less than 1 nm and less than 1000 nm) or on the order of subnanometers (less than 1 nm, for example, not less than 0.1 nm and less than 1 nm) smaller than that. The in-plane dimension is not limited to the order of nanometers (that is, not less than 1 nm and less than 1000 nm), and may be in the order of microns (not less than 1 μm and less than 1000 μm). The two-dimensional substance includes one or more of nanoflakes and a laminate of nanoflakes as described above. The nanoflakes may also be referred to as a nanosheet or a two-dimensional (nano) sheet. The thickness of one layer of the nanoflake may be, for example, 0.01 nm or more, particularly 0.8 nm or more and, for example, 20 nm or less, and particularly 3 nm or less. The in-plane dimension of the nanoflake may be, for example, 0.1 μm or more, particularly 1 μm or more, and may be, for example, 200 μm or less, and particularly 40 μm or less. The nanoflake can be constituted by aggregation of nanofibers.

The laminate of nanoflakes may also be referred to as a multilayer MQO. The distance (interlayer distance or void dimension) between two adjacent nanoflakes (or two adjacent MQO layers) is not particularly limited.

Each dimension described above can be obtained as a number average dimension (number average of at least 40 nanoflakes) based on a photograph observed with a scanning electron microscope (SEM), a transmission electron microscope (TEM), or an atomic force microscope (AFM) (if necessary, the sample is processed by a method such as a focused ion beam (FIB)), or a distance in a real space calculated from a position on a reciprocal lattice space of the (002) plane measured by X-ray diffraction (XRD).

However, it should be noted that in the present disclosure, the form of MQO is not limited to the above-described form, and may have any suitable form. It should also be noted that the composite material of the present embodiment is only required to contain an MQO-containing material and a resin having a negative zeta potential, and may have any appropriate form.

The MQO-containing material may typically have a peak in a range in which a diffraction angle 2θ is not less than 2° and not more than 12° in an X-ray diffraction (XRD) pattern. Although the present disclosure is not bound by any theory, the fact that the MQO-containing material has a peak in the range of 2θ of not less than 2° and not more than 12° in the XRD pattern is considered to mean that the MQO has a crystal structure different from that of a well-known metal oxide.

In the present disclosure, the XRD pattern is a pattern (the vertical axis represents the intensity, and the horizontal axis represents 2θ) obtained by scanning in the θ-axis direction with an XRD analyzer using CuKα rays (=about 1.54 Å) as characteristic X-rays, and may also be referred to as an “XRD profile”. The peaks in the XRD pattern can be identified visually or using the software used with the XRD analyzer.

Although the following description is not limited to the present embodiment, the material of the present embodiment (more specifically, MQO) may have peaks at Raman shift of at least 275 to 295 cm⁻¹, 435 to 455 cm⁻¹, and 665 to 745 cm⁻¹ in a Raman spectrum obtained using a laser with a wavelength of 514 nm, for example.

Although the following description is not limited to the present embodiment, the material of the present embodiment (more specifically, MQO) has, for example, an anatase type crystal structure, a lepidocrocite type crystal structure, or a mixed crystal structure thereof. More preferably, the material of the present embodiment has a lepidocrocite type crystal structure.

Although the following description is not limited to the present embodiment, the material of the present embodiment (more specifically, MQO) may have peaks at Raman shift of at least 275 to 295 cm⁻¹, 435 to 455 cm⁻¹, and 665 to 745 cm⁻¹ in a Raman spectrum obtained using a laser with a wavelength of 514 nm, for example, and X is the largest when the intensities of the respective peaks are defined as X, Y, and Z.

Although the following description is not limited to the present embodiment, more preferably, the material of the present embodiment (more specifically, MQO) may have peaks at Raman shift of at least 180 to 200 cm⁻¹, 275 to 295 cm⁻¹, 375 to 395 cm⁻¹, 435 to 455 cm⁻¹, and 665 to 745 cm⁻¹ in a Raman spectrum obtained using a laser with a wavelength of 514 nm, for example, and X is the largest when the intensities of the respective peaks are defined as V, X, Y, Z, and W.

In the present disclosure, the Raman spectrum is measured by a Raman spectrometer using a laser beam having a wavelength of 514 nm as an excitation light source (the vertical axis represents the intensity, and the horizontal axis represents the Raman shift). The peaks in the Raman spectrum can be identified visually or using the software used with the Raman spectrometer.

Although the following description is not limited to the present embodiment, the material of the present embodiment (more specifically, MQO) is considered to have an anionic terminal such as an O-terminal or an OH-terminal on the surface of the material, and it is known that protons and counter cations are dissociated in a solvent such as water, and the material is negatively charged. The fact that the surface is negatively charged can be confirmed, for example, from the fact that a negative potential is obtained when the zeta potential of a liquid in which MQO is dispersed in water is measured.

In addition, the MQO-containing material may contain an unreacted first raw material and/or second raw material as an impurity, and may contain a substance derived from the first raw material, the second raw material, and/or the protic solvent. For example, when a quaternary ammonium salt is used as the second raw material, N may exist (remain) in any form in the MQO-containing material. Although the following description is not limited to the present embodiment, the MQO-containing material may contain ammonium ions and tetramethylammonium ions. For example, when the MAX raw material is used as the first raw material, in the present disclosure, the MQO-containing material may contain a relatively small amount of remaining A atoms, for example, 10 mass % or less with respect to the original A atoms. The remaining amount of A atoms can be preferably 8 mass % or less, and more preferably 6 mass % or less. However, even if the remaining amount of A atoms exceeds 10 mass %, there may be no problem depending on use conditions and the like.

The composite material of the present embodiment contains the MQO-containing material and a resin having a negative zeta potential. When the composite material contains a resin having a negative zeta potential, as described above, the electrostatic repulsion between the negatively charged material of the present embodiment (MQO-containing material) and the resin having a negative zeta potential keeps the dispersibility of both materials high. In addition, the fluidity of the slurry is maintained, thus enabling film formation by, for example, a spray method.

The form of the composite material may be a fluid including a liquid, or a solid.

When the composite material is a fluid material, the composite material has an MQO-containing material (for example, MQO particles), a resin having a negative zeta potential, and a liquid medium. The resin may be, for example, a water-soluble polymer. The composite material (fluid material) of the present embodiment may be an aqueous dispersion, a slurry, a paste, or the like in which an MQO-containing material is dispersed in a mixed medium of a water-soluble polymer and a liquid medium. In any form of the fluid material, the MQO particles according to the present embodiment having high dispersibility are well dispersed without being aggregated in the mixed medium. Examples of the mixed medium include an aqueous polymer solution in which the proportion of the water-soluble polymer in the total of the water-soluble polymer and the liquid medium (for example, water) is more than 0 mass % and not more than 20 mass %, and preferably not more than 10 mass %. Examples of the water-soluble polymer include, as a polymer (resin) having a negative zeta potential, an alkyl polymer, a polymer having an amide bond (—NHCO—) (resin having an amide bond), a polymer having a urethane bond (resin having a urethane bond), a polymer having an ester bond, a polymer having an ether bond, and an acrylic polymer (acrylic resin). In the present embodiment, it is known that these resins have one or more of an anionic functional group and an anionic segment, and protons and counter cations are dissociated in a solvent such as water, and as a result, the resins are negatively charged. Since the MQO is negatively charged, a composite material is obtained in which both of the MQO and the polymer are dispersed by electrostatic repulsion between the MQO and the negatively charged polymer. Examples of the anionic functional group include a hydroxy group, a hydroxy base, a carboxy group, a carboxy base, a sulfonic acid group, a sulfonic acid base, a phosphoric acid group, a phosphoric acid base, and a thiol group. Examples of the polymer include polyvinyl alcohol, polyethylene glycol, polyacrylic acid, polyacrylate, poly(vinylphosphonic acid), poly(vinylphosphonate), a polymer having an oxoacid represented by polyphosphoric acid as a repeating unit, polyvinyl sulfonic acid, and polyvinyl sulfonate. The content of the anionic functional group and the anionic segment in the polymer may be 50 mol % or less. The polymer may be, for example, a self-emulsifying resin having an anionic functional group and an anionic segment, and having an amide bond or a urethane bond, or an acrylic resin. Examples of the resin having an amide bond or a urethane bond include polyamideimide (PAI), polyacrylamide (PMA), nylon (polyamide resin), DNA (deoxyribonucleic acid), acetanilide, and acetaminophen. Examples of the acrylic resin include polymers polymerized from monomers having an acrylic group, such as monofunctional acrylates such as methyl (meth)acrylate, ethyl (meth)acrylate, propyl (meth)acrylate, isopropyl (meth)acrylate, isobutyl (meth)acrylate, t-butyl (meth)acrylate, and 3-hydroxyethyl (meth)acrylate, and bifunctional acrylates such as ethylene glycol di(meth)acrylate, propylene glycol di(meth)acrylate, and butylene glycol di(meth)acrylate. In addition, examples thereof include an alkyl polymer having an acrylic group at at least one terminal thereof, a polymer having an ether bond, and the like, and further include polymers having, on a side chain of these polymers, a reactive functional group such as a hydroxyl group, a carboxyl group, an amino group, an epoxy group, a mercapto group, an oxazoline group, or the like. The resin is preferably one or more of a resin having an amide bond or a urethane bond and an acrylic resin.

As the liquid medium, an organic medium may be used instead of water or used as a mixed medium with water. Examples of the organic medium include acetonitrile, N, N-dimethylacetamide, N, N-dimethylformamide, DMSO, DMF, NMP, acetone, 2-methyl-2-propanol, isopropyl alcohol, ethanol, and methanol.

The proportion of the MQO-containing material in the fluid composite material can be appropriately set according to the application. The proportion of the MQO-containing material in the fluid composite material may be, for example, not less than 0.1 mass % and not more than 99.9 mass %.

When the composite material is a solid material, examples of the composite material include a composite material (composite) containing a resin (polymer) having a negative zeta potential together with the MQO-containing material. Examples of the polymer (resin) having a negative zeta potential include an alkyl polymer, a polymer having an amide bond (—NHCO—) (resin having an amide bond), a polymer having a urethane bond (resin having a urethane bond), a polymer having an ester bond, a polymer having an ether bond, and an acrylic polymer (acrylic resin). In the present embodiment, it is known that these resins have one or more of an anionic functional group and an anionic segment, and protons and counter cations are dissociated in a solvent such as water, and as a result, the resins are negatively charged. Since the MQO is negatively charged, a composite material is obtained in which both of the MQO and the polymer are dispersed by electrostatic repulsion between the MQO and the negatively charged polymer. Examples of the anionic functional group include a hydroxy group, a hydroxy base, a carboxy group, a carboxy base, a sulfonic acid group, a sulfonic acid base, a phosphoric acid group, a phosphoric acid base, and a thiol group. Examples of the polymer include polyvinyl alcohol, polyethylene glycol, polyacrylic acid, polyacrylate, poly(vinylphosphonic acid), poly(vinylphosphonate), a polymer having an oxoacid represented by polyphosphoric acid as a repeating unit, polyvinyl sulfonic acid, and polyvinyl sulfonate. The content of the anionic functional group and the anionic segment in the polymer may be 50 mol % or less. The polymer may be, for example, a self-emulsifying resin having an anionic functional group and an anionic segment, and having an amide bond or a urethane bond, or an acrylic resin. Examples of the resin having an amide bond or a urethane bond include polyamideimide (PAI), polyacrylamide (PMA), nylon (polyamide resin), DNA (deoxyribonucleic acid), acetanilide, and acetaminophen. Examples of the acrylic resin include polymers polymerized from monomers having an acrylic group, such as monofunctional acrylates such as methyl (meth)acrylate, ethyl (meth)acrylate, propyl (meth)acrylate, isopropyl (meth)acrylate, isobutyl (meth)acrylate, t-butyl (meth)acrylate, and 3-hydroxyethyl (meth)acrylate, and bifunctional acrylates such as ethylene glycol di(meth)acrylate, propylene glycol di(meth)acrylate, and butylene glycol di(meth)acrylate. In addition, examples thereof include an alkyl polymer having an acrylic group at at least one terminal thereof, a polymer having an ether bond, and the like, and further include polymers having, on a side chain of these polymers, a reactive functional group such as a hydroxyl group, a carboxyl group, an amino group, an epoxy group, a mercapto group, an oxazoline group, or the like. The resin is preferably one or more of a resin having an amide bond or a urethane bond and an acrylic resin.

The proportion of the polymer in the solid composite material can be determined in view of the desired characteristics. The proportion of the polymer in the composite material can be, for example, not less than 0.1 mass % and not more than 99.9 mass %.

The proportion of the MQO-containing material in the solid composite material can be appropriately set according to the application. The proportion of the MQO-containing material in the solid composite material may be, for example, not less than 0.1 mass % and not more than 99.9 mass%.

Since the dispersibility of the MQO-containing material according to the present embodiment is high, the MQO-containing material is well kneaded with the polymer, and a polymer composite in which the MQO-containing material is well dispersed without being aggregated is obtained. The stirring of the MQO-containing material and the polymer can be performed using a dispersing device such as a homogenizer, a propeller stirrer, a thin-film spin system mixer, a planetary mixer, a mechanical shaker, a Vortex mixer, or a high-pressure disperser.

When the composite material of the present embodiment is a solid, for example, the composite material may be in the form of a film. The composite material in the form of a film can be formed using, for example, a slurry of a mixture of the MQO particles and the polymer, which is the fluid composite material. The composite material in the form of a film is formed by, for example, applying a slurry of a mixture of the MQO particles and the polymer to a base (for example, a substrate), but the application method is not limited. Examples of the application method include a method of performing spray coating using a nozzle such as a one-fluid nozzle, a two-fluid nozzle, or an air brush, a method such as slit coating, screen printing, or metal mask printing using a table coater, a comma coater, or a bar coater, and a coating method by spin coating, dip coating, or dropping. The application and drying may be repeated a plurality of times as necessary until a film having a desired thickness is obtained. Drying and curing may be performed at a temperature of 400 °C or lower using, for example, an atmospheric-pressure oven or a vacuum oven.

Although the present disclosure is not bound by any theory, it is considered that one of the reasons why the dispersibility of the MQO particles according to the present embodiment is high is that the absolute value of the zeta (ζ) potential of the negatively charged MQO particles is large, and the electrostatic repulsion with the negatively charged resin is large. The absolute value of the zeta potential of the MQO particles can be, for example, 1 or more, and is preferably 10 or more when the zeta potential of the MQO particles is measured by the following method. For the measurement of the zeta potential, a dispersion is used which is prepared by using ion-exchanged water as a dispersion medium, adjusting the content of the MQO particles or TiO₂ particles used in Comparative Examples to be in a range of 0.01 to 0.1 mass%, and performing permeation treatment with a Vortex mixer for 5 minutes. Using the dispersion, measurement is performed in the atmosphere using a zeta potential measuring apparatus (device name; Zetasizer Nano-ZS, Malvern Panalytical, Malvern, U.K.).

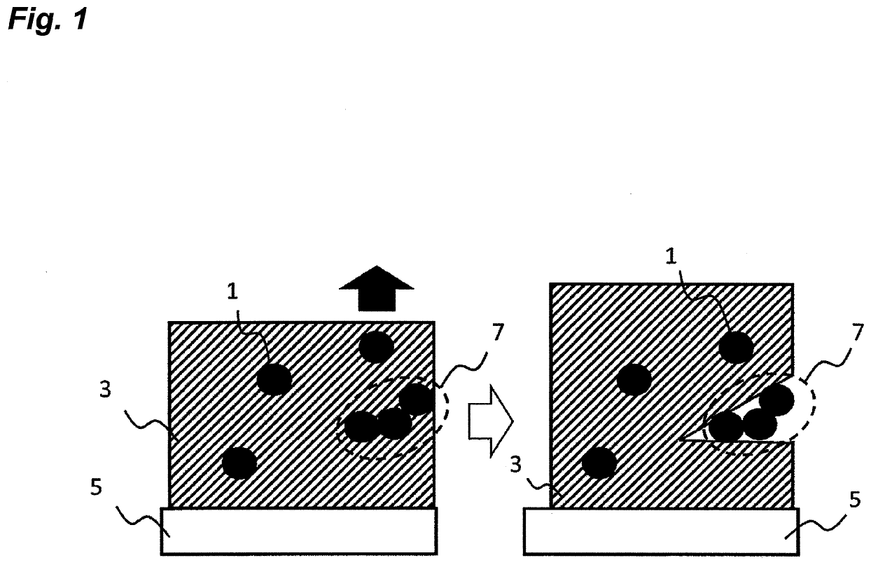

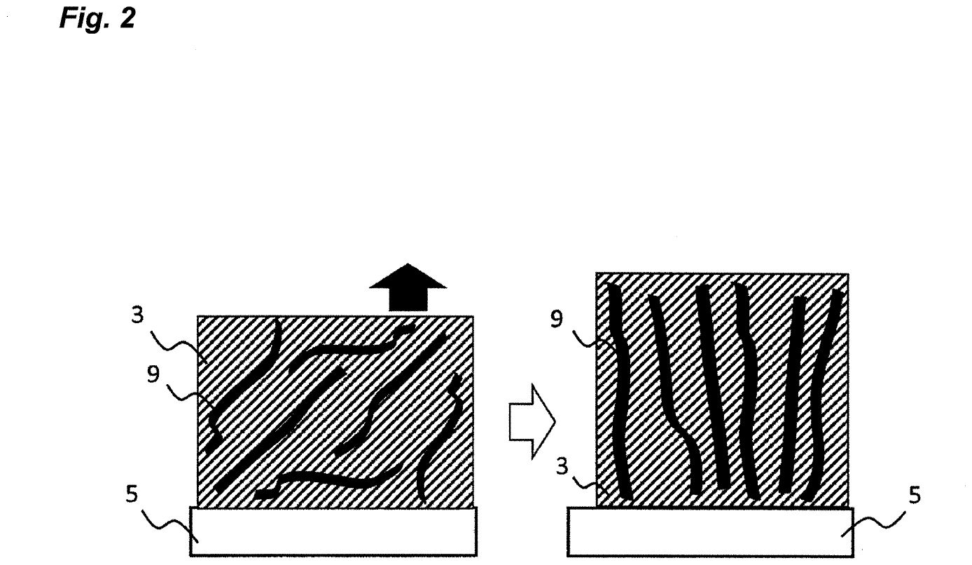

When the composite material of the present embodiment is in the form of a film, a film having high film strength can be obtained. As schematically shown in FIG. 1, in a polymer composite obtained by mixing TiO₂ 1, which has been conventionally used as a filler, and a resin 3 without adding a dispersant and then applying the mixture onto a PET substrate 5, an aggregated portion 7 surrounded by a broken line, in which TiO₂ 1 is aggregated, is likely to be formed (left in FIG. 1). When the film of the polymer composite is pulled in the direction of the black arrow for, for example, film strength measurement (tensile test), as shown in the right of FIG. 1, fracture failure is likely to occur starting from the aggregated portion 7. On the other hand, as schematically shown in FIG. 2, in a polymer composite obtained by mixing a material 9 containing a predetermined nanofiber and/or two-dimensional substance and the resin 3 without adding a dispersant and then applying the mixture onto the PET substrate 5, the material 9 is not aggregated, so that the material 9 can be dispersed. When a dispersant is added at the time of mixing with a resin, the service life of the composite material is short due to deterioration of the dispersant, whereas such a problem does not occur in the composite material of the present embodiment. As a result, for example, when the film is pulled in the direction of the black arrow for film strength measurement (tensile test), the film is hardly broken and exhibits high strength.

Although the composite material in certain embodiments has been described in detail above, the present disclosure can be modified in various ways. It should be noted that the material of the present disclosure may be produced by a method different from the production method in the above-described embodiment.

### EXAMPLES

Hereinafter, the present disclosure will be described more specifically with reference to Examples. The present disclosure is not limited by the following Examples, and can be implemented with appropriate modifications within the scope that can be consistent with the above-described and later-described aspect, and any of them is included in the technical scope of the present disclosure.

### Example 1

### TiCO/Polyurethane Composite Material Film

### Preparation of Slurry Containing TiCO

First, a container (100 mL I-Boy, wide-mouth bottle) was charged with 1 g of titanium diboride (TiB₂, manufactured by Alfa Aesar) and 10 mL of a 25 mass % aqueous tetramethylammonium hydroxide (TMAH) solution (manufactured by Alfa Aesar). Thereto was placed a stirrer chip having a length substantially equal to the inner diameter of the circular bottom surface of the container (35 mm). While the container was kept at 80 °C in an oil bath, the mixture in the container was stirred with a stirrer chip and maintained for 120 hours, thereby allowing the reaction to proceed. The reaction mixture in the container was then transferred to a centrifuge tube. Centrifugation was performed using a centrifuge under conditions of 3500G and 5 minutes to precipitate the solid content. (i) After centrifugation, the supernatant was discarded, (ii) 40 mL of ethanol (manufactured by Fisher Chemical Co., Ltd.) was added to the remaining precipitate in the centrifuge tube, the mixture was subjected to dispersion treatment using a Vortex mixer for 5 minutes (reslurring), and (iii) the resultant dispersion was centrifuged under the same conditions as described above. The operations (i) to (iii) were repeated until the pH of the supernatant was 8 or less. When a series of the operations (i) to (iii) was repeated three times, the pH of the supernatant became 8 or less. The supernatant at this time was discarded, and the repeated operation was terminated. Then, 40 mL of pure water was added to the remaining precipitate in the centrifuge tube, and the mixture was shaken and stirred for 5 minutes using a Vortex mixer. Thereafter, the mixture was centrifuged with a centrifuge under the conditions of 3500 G and 30 minutes, and the supernatant was recovered as a slurry containing TiCO as MQO.

### Analysis of TiCO Obtained Above

### SEM Observation

The shape of TiCO was observed by an SEM. Specifically, the slurry containing TiCO prepared above was diluted 1000 times, and dropped onto an Al porous substrate. A Pt/Pd vapor deposition treatment (40 mA, 30 s) was performed, and the result of observation with a SEM showed that nanofibers having a width of 20 nm were obtained.

### Measurement of Zeta Potential

The zeta potential of the TiCO slurry was measured and found to be −80 mV. The absolute value of the zeta potential of the TiCO slurry was larger than the absolute value of −0.5 mV, which is the zeta potential of the conventional titanium dioxide (P-25) slurry (aqueous dispersion). Subsequently, the zeta potential of the polymer was measured, and the zeta potential of the polyurethane (RESAMINE D-4080 (polyether/carbonate) manufactured by Dainichiseika Color & Chemicals Mfg. Co., Ltd.) was −35.5 mV, the zeta potential of the acrylic resin material (ARON (registered trademark) NW-400, manufactured by Toagosei Co., Ltd.) was −30.5 mV, and the zeta potential of the poly(ethyleneimine) (aqueous poly(ethyleneimine) solution, manufactured by Sigma-Aldrich Co. LLC) was 10.5 mV.

### Raman Spectroscopy

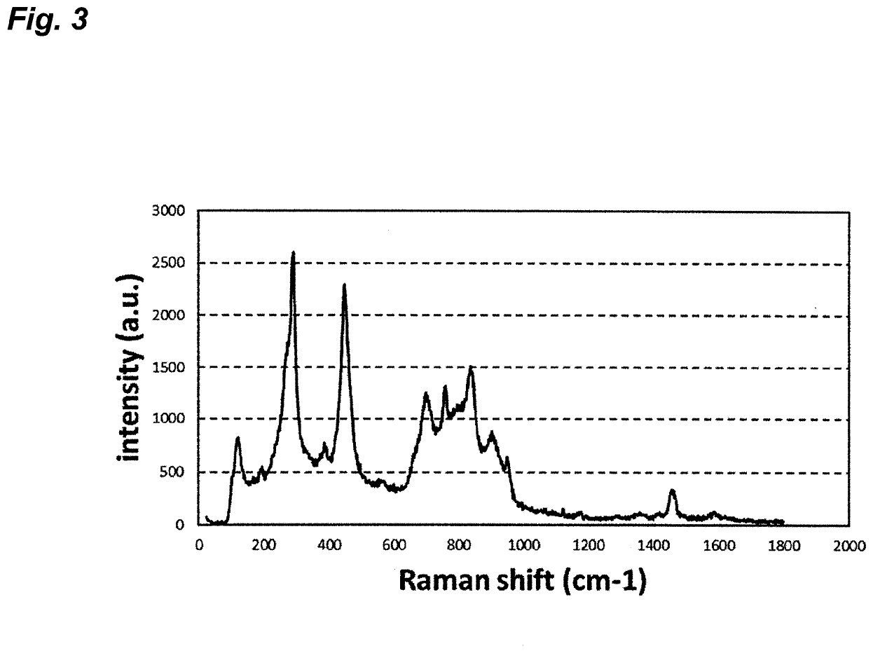

Measurement was performed on the TiCO slurry with a Raman spectrometer (Renishaw, product number: InVia) using a laser beam having a wavelength of 514 nm as an excitation light source to obtain a Raman spectrum. An example of the measurement result is shown in FIG. 3. FIG. 3 shows that the sample has peaks at Raman shift of 275 to 295 cm⁻¹, 435 to 455 cm⁻¹, and 665 to 745 cm⁻¹, and has a lepidocrocite type crystal structure. FIG. 3 also shows that the sample has peaks at Raman shift of at least 180 to 200 cm⁻¹, 275 to 295 cm⁻¹, 375 to 395 cm⁻¹, 435 to 455 cm⁻¹, and 665 to 745 cm⁻¹ in the Raman shift, and X is the largest when the intensities of the respective peaks are defined as V, X, Y, Z, and W. (Preparation of TiCO film)

In order to analyze the component composition, structure, and the like of the obtained TiCO, a TiCO film was prepared as follows using the slurry containing TiCO. First, 1 mL of the slurry containing TiCO was collected, mixed with 20 mL of pure water, and then vibrated with a Vortex mixer for 5 minutes. The resulting mixture was subjected to suction filtration overnight using a Nutsche. As a filter for suction filtration, a membrane filter (Durapore, pore diameter 0.22μm, manufactured by Merck Ltd.) was used. After suction filtration, the precursor membrane on the filter was dried overnight in a vacuum oven at 80 °C, and the filter was removed, thereby obtaining a film (free-standing film).

### X-ray Photoelectron Spectroscopy (XPS) Analysis

When the obtained TiCO film (free-standing film) was analyzed by X-ray photoelectron spectroscopy (XPS), peaks corresponding to Ti2p, C1s, O1s, and N1s were observed in the obtained XPS spectrum, and thus Ti, C, O, and N were detected. Since N is considered to be the residual content of TMAH of the raw material, the material of the free-standing film is considered to be composed of Ti, C, and O.

### Measurement of XRD Pattern

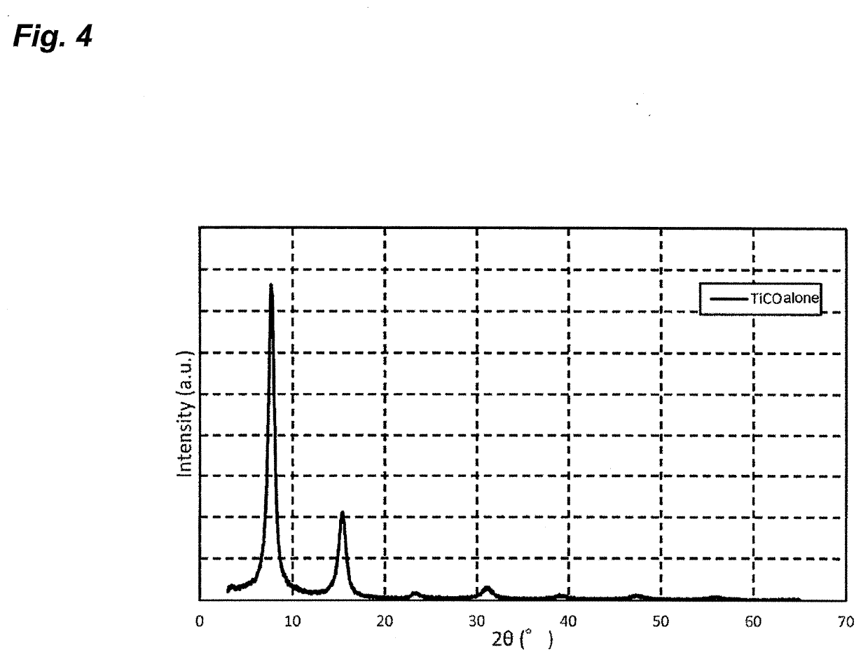

An XRD pattern was measured for the obtained film (free-standing film) using an XRD apparatus (MiniFlex, manufactured by Rigaku Corporation) (characteristic X-ray: CuKα=1.54 Å). The obtained XRD pattern is shown in FIG. 4. As understood from FIG. 4, this material had a peak of the (001) plane at 2θ=7.7° and a peak of the (002) plane at 2θ=15.4°. This indicates that this material has a periodic structure in the thickness direction.

### Preparation of Resin Slurry and Mixing of Resin Slurry and Slurry Containing TiCO

Polyurethane (RESAMINE D-4080 (polyether/carbonate) manufactured by Dainichiseika Color & Chemicals Mfg. Co., Ltd.) and pure water were blended at a ratio of 1:9, and stirred with a Vortex mixer for 5 minutes to obtain a resin slurry.

The resin slurry, pure water, and a slurry containing TiCO were mixed so as to obtain a TiCO/polyurethane composite material in which the ratio of polyurethane to TiCO (after film formation and drying) was 30 mass %, and the mixture was stirred with a Vortex mixer for 5 minutes to obtain a mixed slurry of TiCO and a resin.

### Preparation of TiCO/Polyurethane Composite Film (1) Suction Filtration

The mixed slurry of TiCO and a resin prepared above was subjected to suction filtration overnight using a Nutsche. As a filter for suction filtration, a membrane filter (Durapore, pore diameter 0.22 μm, manufactured by Merck Ltd.) was used. After suction filtration, the precursor membrane on the filter was dried overnight in a vacuum oven at 80 °C, and the filter was removed, thereby obtaining a TiCO/polyurethane composite film (free-standing film, also referred to as “TiCO/polyurethane composite material film”).

### Preparation of TiCO/Polyurethane Composite Film (2) Spray Coating

The mixed slurry of TiCO and a resin prepared above was applied to a PET substrate by spray coating using an air brush as a spray nozzle. Spraying and drying with a dryer were repeated until the film thickness of the TiCO/polyurethane composite material reached 5 μm. After completion of the application, drying was performed at 80 °C for about 30 minutes in an atmospheric-pressure oven to obtain a film of a TiCO/polyurethane composite material (also referred to as “TiCO/polyurethane composite material film”).

### Example 2

### TiCO/Acrylic Resin Composite Material Film

Except that the polyurethane in Example 1 was changed to an acrylic resin material (ARON (registered trademark) NW-400, manufactured by Toagosei Co., Ltd.), the same procedure as in Example 1 was carried out to obtain a mixed slurry of TiCO and a resin, and a TiCO/acrylic resin composite material film by spray coating.

### Comparative Example 1

### TiO₂/Polyurethane Composite Material Film

Except that TiCO in Example 1 was changed to TiO₂, the same procedure as in Example 1 was carried out to obtain a mixed slurry of TiO₂ and a resin, and a TiO₂/polyurethane composite material film by spray coating.

### Comparative Example 2

### TiCO/Poly(Ethyleneimine) Composite Material Film

Except that the polyurethane in Example 1 was changed to poly(ethyleneimine) (aqueous poly(ethyleneimine) solution, manufactured by Sigma-Aldrich Co. LLC), the same procedure as in Example 1 was carried out to obtain a mixed slurry of TiCO and a resin and a TiCO/poly(ethyleneimine) composite material film by spray coating.

### Evaluation

The following evaluations were performed using the composite material films of Examples and Comparative Examples.

### Measurement of XRD Pattern of TiCO/Polyurethane Composite Film

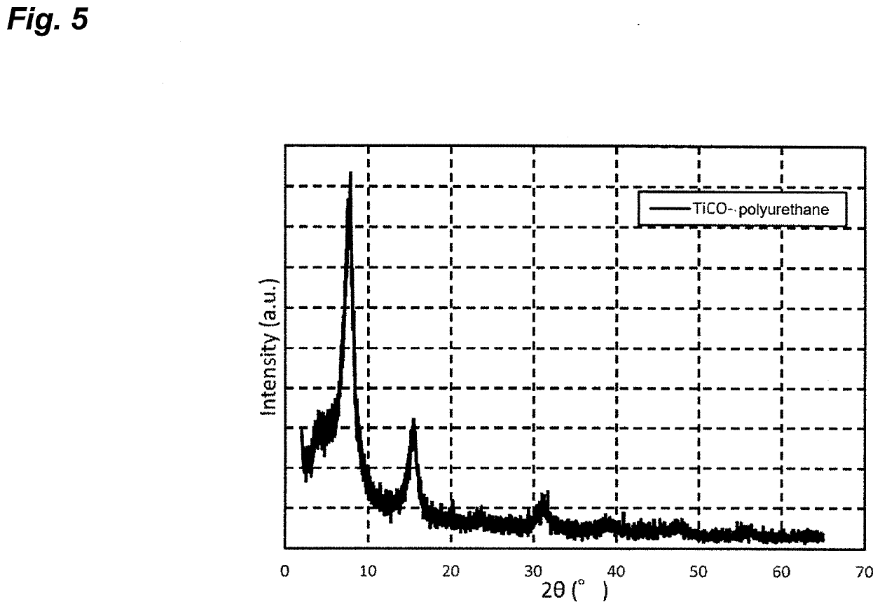

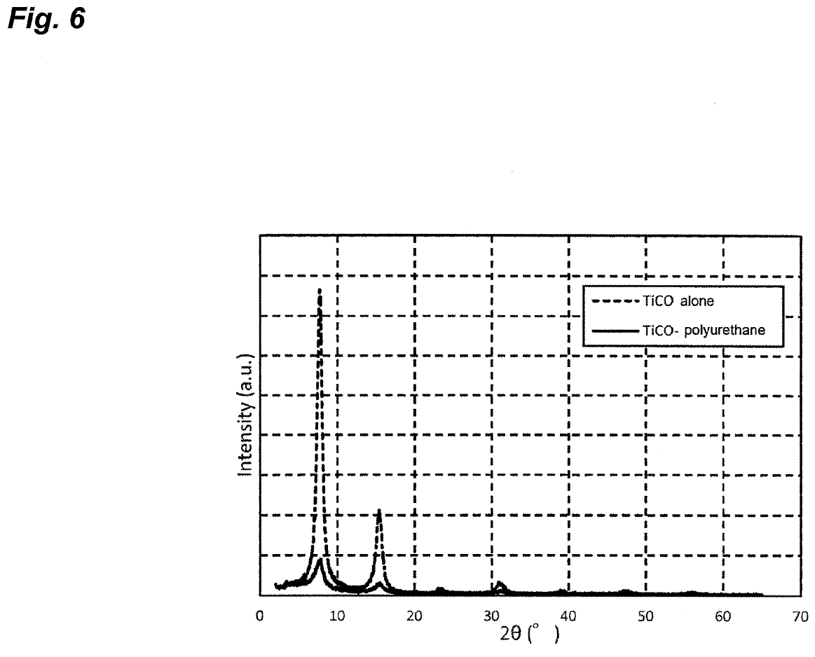

An XRD pattern of the TiCO/polyurethane composite film (free-standing film) obtained by the above “Preparation of TiCO/polyurethane composite film (1) suction filtration” was measured using an XRD apparatus (MiniFlex, manufactured by Rigaku Corporation) (characteristic X-ray: CuKα=1.54 Å). The obtained XRD pattern is shown in FIG. 5. FIG. 6 shows a view in which the XRD profiles of FIG. 5 and FIG. 4 are overlaid. As understood from FIG. 5, the TiCO/polyurethane composite material had a peak of the (001) plane at 2θ=7.7° and a peak of the (002) plane at 2θ=15.5°. As shown in FIG. 6, these peak positions are not significantly different from those of the TiCO film alone, which indicates that the TiCO is mixed with the resin and still has a periodic structure in the thickness direction.

### Evaluation of Film Strength

A tape peeling test was performed as follows using the TiCO/polyurethane composite material film obtained by the above “Preparation of TiCO/polyurethane composite film (2) spray coating”, the TiCO/acrylic resin composite material film obtained in the same manner, and the TiO₂/polyurethane composite material film obtained in the same manner, to measure the strength of each composite material film. For the TiCO/poly(ethyleneimine) composite material film, spray coating could not be performed due to gelation. This is considered to be because negatively charged TiCO and positively charged poly(ethyleneimine) were aggregated by electrostatic attraction, and the dispersibility of TiCO in the composite material film was poor.

Details of the strength measurement of the composite material film are as follows. An adhesive tape (3M, 6122MP Scotch (registered trademark) Magic (trademark) TAPE, ¾ inch wide) was attached to a part of the upper surface of the composite material film formed on the PET substrate, and then peeled off. The presence or absence of cohesive failure of the composite material film was visually observed, that is, separation in the film due to transfer of a part of the composite material film to the tape adhesive surface was visually observed.

As a result, cohesive failure could not be confirmed in the TiCO/polyurethane composite material film and the TiCO/acrylic resin composite material film. On the other hand, cohesive failure was confirmed in the titanium dioxide/polyurethane composite material film. This is considered to be because the dispersibility of titanium dioxide (TiO₂) in the aqueous dispersion was poor, and as a result, the dispersibility of titanium dioxide (TiO₂) in the composite material film was poor.

### Evaluation of Thermal Conductivity

The specific heat capacity and the thermal diffusivity of the TiCO/polyurethane composite film (free-standing film) obtained by the “Preparation of TiCO/polyurethane composite film (1) suction filtration” were measured according to a laser flash method (ASTM E1461) using a desktop xenon flash analyzer (device name; LFA 467 HyperFlash, manufactured by NETZSCH), and the thermal conductivity was calculated. The in-plane thermal diffusivity of a flat plate sample was determined by heating the surface of the sample by pulse heating with a xenon lamp, and observing the heat diffusion in the thickness direction in a portion located at the in-plane direction from the heated portion, as a temporal change in temperature of the back surface of the sample.

As a result, the specific heat capacity (c_{ρ}) was 1.86 J/(g·K), the thermal diffusivity (diffusivity) (a) was 2.85 mm²/s, and the in-plane thermal conductivity (in-plane conductivity) (l) was 7.36 W/(m·K). For reference, the in-plane thermal conductivity of the TiCO film was also measured and found to be 8.67 W/(m·K). From this, it is considered that in the composite material film according to the present embodiment, TiCO was well dispersed, and thus the decrease in thermal conductivity was suppressed even in a state of being mixed with the resin. On the other hand, suction filtration using a membrane filter was performed using an aqueous dispersion of titanium dioxide (TiO₂), but a film (free-standing film) was not obtained. This is considered to be a result of poor dispersibility of titanium dioxide (TiO₂) in the aqueous dispersion of titanium dioxide (TiO₂) and the shape of nanoparticles. It is considered that TiCO is a one-dimensional material (nanofiber) and/or a two-dimensional material, and is easy to form a film, whereas titanium dioxide has a particle shape, and thus is difficult to form a coating film. Since a film containing titanium dioxide (TiO₂) could not be formed, the thermal conductivity of the film could not be evaluated.

### Evaluation of Dispersibility

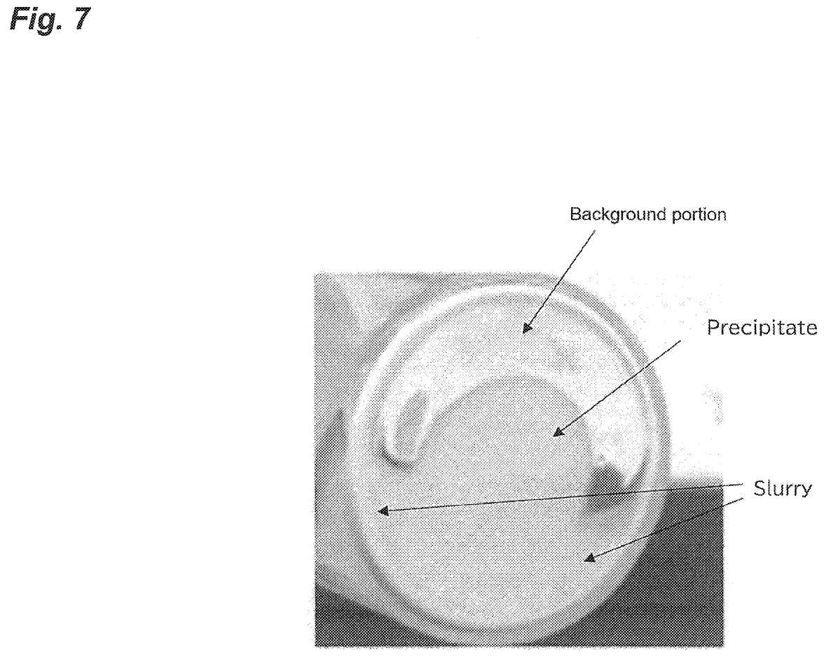

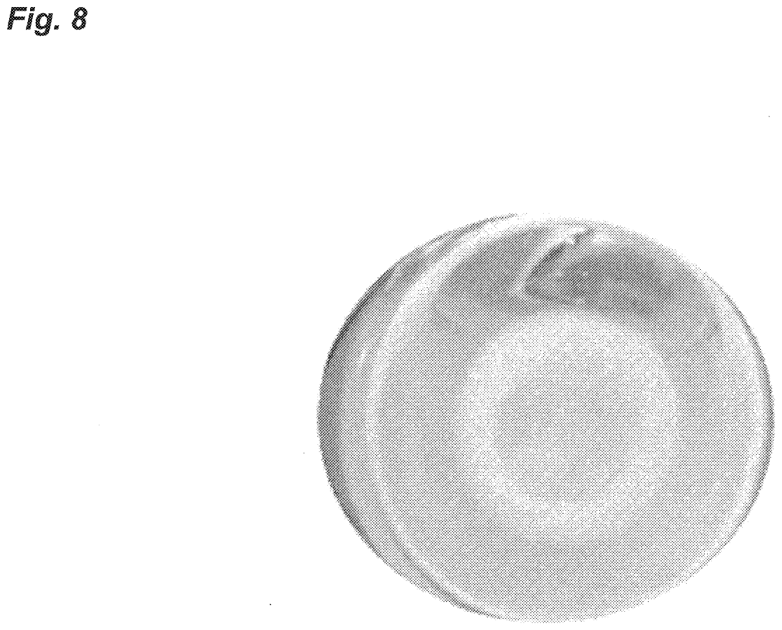

In order to separately evaluate the dispersibility, the present inventors placed each of an aqueous dispersion of titanium dioxide (TiO₂) (titanium dioxide concentration: 1 mass %), an aqueous polyurethane dispersion of titanium dioxide (TiO₂) (titanium dioxide concentration: 1 mass %, and polyurethane concentration: 1 mass %), an aqueous poly(ethyleneimine) dispersion of TiCO particles (TiCO particle concentration: 1 mass %, and poly(ethyleneimine) concentration: 1 mass %), an aqueous polyurethane dispersion of TiCO particles according to the present embodiment (TiCO particle concentration: 1 mass %, polyurethane concentration: 1 mass %), and an aqueous acrylic resin dispersion of TiCO particles according to the present embodiment (TiCO particle concentration: 1 mass %, and acrylic resin concentration: 1 mass %) in a glass container, and left them to stand. Then, the bottom of the glass container after being left for 4 days was visually confirmed. The photographs are shown in FIGS. 7 to 11. In FIG. 7, a white precipitate in a circular shape was confirmed in the central portion of the photograph, and in FIG. 8, a white precipitate in a circular shape was confirmed in the central portion. As is clear from the photographs of FIGS. 7 and 8, titanium dioxide was precipitated on the bottom of the glass container.

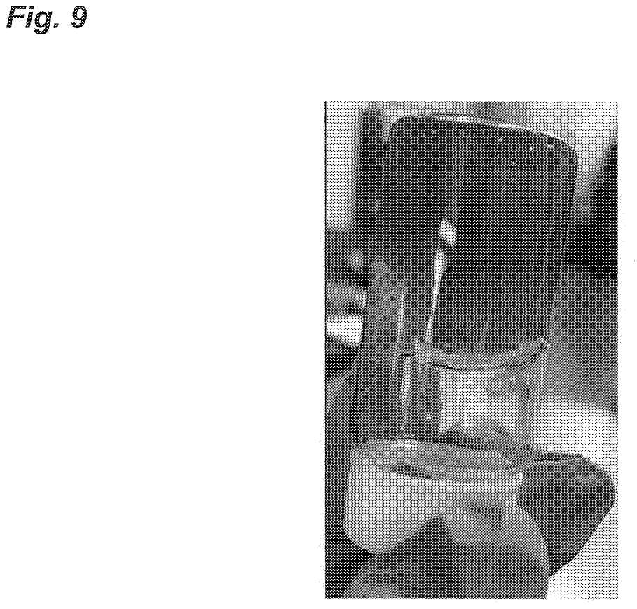

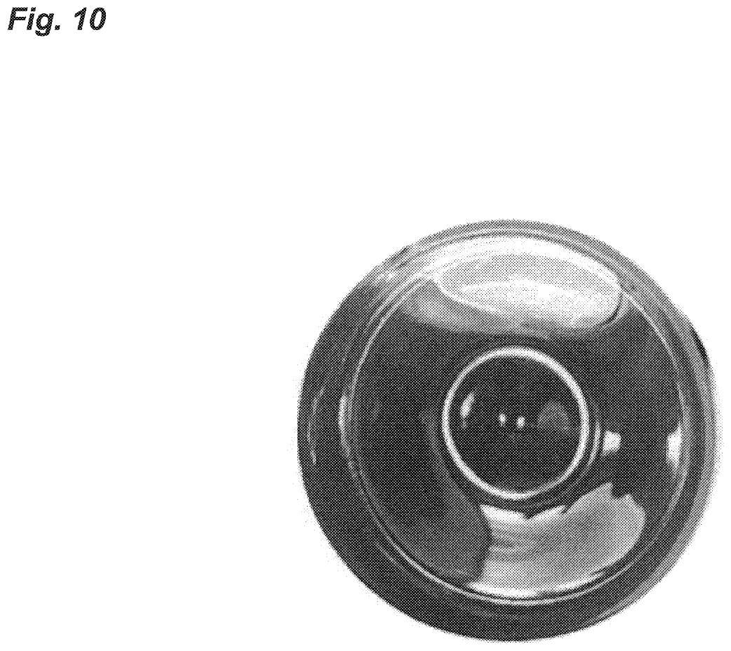

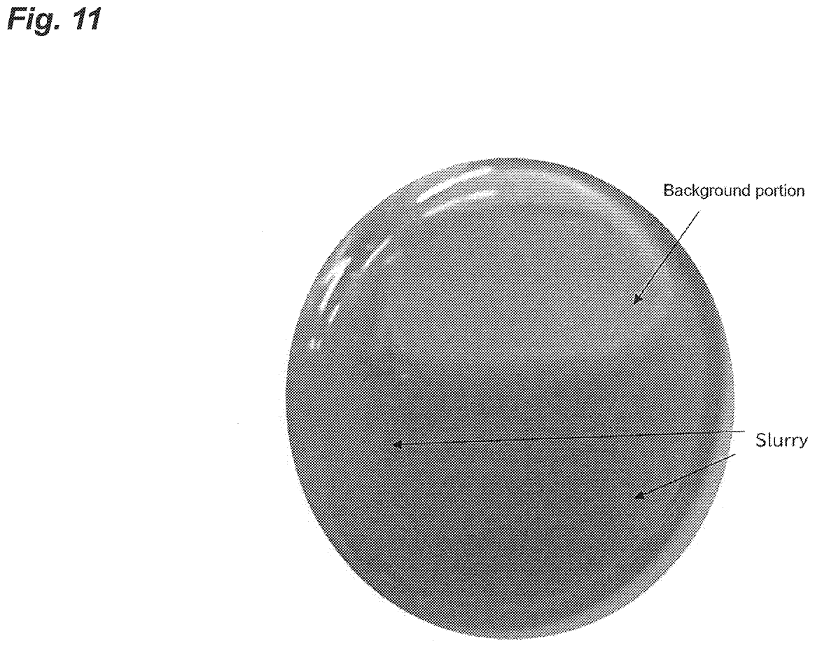

FIG. 9 is a photograph showing a state in which TiCO is not sufficiently dispersed in an aqueous poly(ethyleneimine) solution and is gelled. In this gel-like sample, since the viscosity was too high to perform spray coating, it was confirmed that even when a resin not having a negative zeta potential was mixed with TiCO, a composite material suitable for production of a film or the like could not be provided. On the other hand, as shown in the photograph of FIG. 10, in the aqueous polyurethane dispersion of TiCO (MQO) particles according to the present embodiment, precipitation of TiCO particles was not observed even after 4 days (Note that the upper white portion in the photograph of FIG. 10 is not a precipitate because the background portion was reflected). It is considered that such high dispersibility of the TiCO particles according to the present embodiment contributes to exertion of excellent thermal conductivity or the like of a film or the like containing the TiCO particles. Similarly, as shown in the photograph of FIG. 11, in the aqueous acrylic resin dispersion of TiCO (MQO) particles according to the present embodiment, precipitation of TiCO particles was not observed even after 4 days, and high dispersibility was exhibited.

### REFERENCE SIGNS LIST

1 TiO₂ (filler)
3 resin
5 PET substrate
7 aggregated portion
9 material containing predetermined nanofiber and/or two-dimensional substance

1. A composite material comprising:
a resin having a negative zeta potential; and
a material containing a nanofiber and/or a two-dimensional substance represented by:
MQₐO_{b}
wherein M is one or more elements selected from the group consisting of Groups 3, 4, 5, 6, and 7,
Q is one or more elements selected from the group consisting of Groups 12, 13, 14, 15, and 16, excluding O,
a is not less than 0 and not more than 2, and
b is greater than 0 and not more than 2.

2. The composite material according to claim 1, wherein in an X-ray diffraction pattern, the composite material has a peak in a range of a diffraction angle 2θ of not less than 2° and not more than 12°.

3. The composite material according to claim 2, wherein in a Raman spectrum obtained using a laser with a wavelength of 514 nm, the composite material has peaks at Raman shift of 275 to 295 cm⁻¹, 435 to 455 cm⁻¹, and 665 to 745 cm⁻¹ in a Raman shift.

4. The composite material according to claim 1, wherein in a Raman spectrum obtained using a laser with a wavelength of 514 nm, the composite material has peaks at Raman shift of 275 to 295 cm⁻¹, 435 to 455 cm⁻¹, and 665 to 745 cm⁻¹ in a Raman shift.

5. The composite material according to claim 1, wherein the composite material has an anatase type crystal structure, a lepidocrocite type crystal structure, or a mixed crystal structure thereof.

6. The composite material according to claim 1, wherein the composite material has a lepidocrocite type crystal structure.

7. The composite material according to claim 1, wherein in a Raman spectrum obtained using a laser at a wavelength of 514 nm, the composite material has peaks at Raman shift of at least 180 to 200 cm⁻¹, 275 to 295 cm⁻¹, 375 to 395 cm⁻¹, 435 to 455 cm⁻¹, and 665 to 745 cm⁻¹, and X is the largest when intensities of the respective peaks are defined as V, X, Y, Z and W.

8. The composite material according to claim 1, wherein the resin is one or more of a resin having an amide bond or a urethane bond and an acrylic resin.

9. The composite material according to claim 8, wherein a proportion of the resin in the composite material is 5 mass % or more.

10. The composite material according to claim 1, wherein a proportion of the resin in the composite material is 5 mass % or more.

11. The composite material according to claim 1, wherein the composite material is in the form of a film.

12. The composite material according to claim 1, wherein the composite material is a thermally conductive material.

13. The composite material according to claim 1, further comprising a liquid medium.

14. The composite material according to claim 13, wherein the resin is a water-soluble polymer.

15. The composite material according to claim 14, wherein a proportion of the water-soluble polymer in a total of the water-soluble polymer and the liquid medium is more than 0 mass % and not more than 20 mass %.

16. The composite material according to claim 14, wherein the water-soluble polymer is selected from an alkyl polymer, a polymer having an amide bond, a polymer having a urethane bond, a polymer having an ester bond, a polymer having an ether bond, or an acrylic polymer.

17. The composite material according to claim 13, wherein the liquid medium comprises an organic medium.
